(19) United States
(12) Patent Application Publication
(10) Pub. No.: US 2024/0404897 A1
(43) Pub. Date: Dec. 5, 2024

(54) CHIP COMPLEX WITH EMBEDDED INTERPOSER

(71) Applicant: Advanced Micro Devices, Inc., Santa Clara, CA (US)

(72) Inventors: Deepak Vasant KULKARNI, Austin, TX (US); Raja SWAMINATHAN, Austin, TX (US); Mihir PANDYA, Austin, TX (US); Liwei WANG, Austin, TX (US); Samuel NAFFZIGER, Fort Collins, CO (US)

(21) Appl. No.: 18/676,665

(22) Filed: May 29, 2024

Related U.S. Application Data
(60) Provisional application No. 63/470,099, filed on May 31, 2023.

(51) Int. Cl. H01L 23/13; H01L 23/00; H01L 23/498; H01L 25/18

(52) U.S. Cl. CPC H01L 23/13; H01L 23/49833; H01L 24/08; H01L 24/80; H01L 25/18; H01L 23/49816; H01L 24/16; H01L 2224/08225; H01L 2224/16225; H01L 2224/80895; H01L 2224/80896; H01L 2924/1431

(57) ABSTRACT

A chip complex is provided that includes at least a first IC die present in a first common tier, a passive interposer, and a plurality of IC dies present in a second common tier. The passive interposer includes an interconnect formed in a back end of the line (BEOL) region. The first IC die present in the first common tier are hybrid bonded to a top side of the passive interposer. The plurality of IC dies present in the second common tier are also hybrid bonded to a bottom side of the passive interposer.

### CROSS-REFERENCE TO RELATED APPLICATIONS

This application claims priority to the U.S. Provisional Patent Application Ser. No. 63/470,099 filed May 31, 2023 of which is incorporated herein by reference in its entirety.

### BACKGROUND

### Field of the Invention

Implementations described herein generally relate to chip packages having stacked integrated circuit (IC) dies, and in particular, stacked IC dies comprised of at least two tiers separated by a passive interposer, with dies from both tiers being hybrid bonded to the passive interposer.

### Description of the Related Art

Some chip packages having multiple tiers of IC dies utilize a bridge die to provide interconnection between adjacent IC dies disposed on a different tier. Since the bridge die only partially overlaps each of the adjacent IC dies, the beachhead of each adjacent IC available for interfacing bridge die is limited. Thus, the density and number of interconnections available through the beachhead is limited.

Thus, there is a need for an improved multi-tier chip package.

### SUMMARY

A chip complex is provided that includes a plurality of IC dies present in a first common tier, a passive interposer, and a plurality of IC dies present in a second common tier. The plurality of IC dies present in the first common tier are hybrid bonded to a bottom side of the passive interposer. The plurality of IC dies present in the second common tier are hybrid bonded to a top side of the passive interposer.

In one example, the passive interposer covers an entirety of one of the plurality of IC dies present in the first common tier.

In another example, the passive interposer also covers an entirety of a second IC die of the plurality of IC dies present in the first common tier.

In one example, the passive interposer covers an entirety of one of the plurality of IC dies present in the second common tier.

In another example, the passive interposer also covers an entirety of a second IC die of the plurality of IC dies present in the second common tier.

In one example, the passive interposer includes an interconnect formed by BEOL processes disposed on a thinned substrate. Alternatively, passive interposer may consist of only a BEOL region that includes an interconnect formed by BEOL processes, where the substrate has been removed. Optionally, the passive interposer only includes passive routing, such as not having any transistors.

In one example, an integrated circuit (IC) chip complex is provided. The chip complex includes a passive interposer, at least a first (IC) die, and at least two or more second (IC) dies. The passive interposer includes an interconnect formed in a back end of the line (BEOL) region. The first IC die is part of a first common tier that is hybrid bonded to a first side of the passive interposer. The two or more second IC dies is part of a second common tier that is hybrid bonded to a second side of the passive interposer.

In another example, an integrated circuit (IC) chip package is provided. The chip package includes a chip complex mounted to a substrate. The chip complex includes a passive interposer, at least a first (IC) die of a first common tier hybrid bonded to a first side of the passive interposer, and at least two or more second (IC) dies of a second common tier hybrid bonded to a second side of the passive interposer. In some examples, the passive interposer includes an interconnect disposed in a BEOL region, the BEOL region comprising the first and second sides of the passive interposer.

In yet another example, an integrated circuit (IC) memory chip complex is provided that includes a passive interposer, a plurality of memory integrated circuit (IC) dies stacked together, one of the memory IC dies hybrid bonded to a first side of the passive interposer, and at least two or more (IC) dies of a first common tier hybrid bonded to a second side of the passive interposer.

In still another example, an integrated circuit (IC) chip package is provided. The chip package includes a substrate, one or more logic IC dies mounted on the substrate, and a chip complex mounted to the substrate. The chip complex is communicatively coupled to the one or more logic IC dies through the substrate. The chip complex includes a passive interposer and a plurality of memory IC dies stacked together. One of the memory IC dies is hybrid bonded to a first side of the passive interposer. At least two or more (IC) dies of a first common tier are hybrid bonded to a second side of the passive interposer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic illustration of an electronic device having a chip package, the chip package having a chip complex.

FIG. 2 is a block diagram of a method for fabricating a chip complex, the method extendible to form a chip package.

FIGS. 3A-3K are schematic sectional views of a chip complex at different stages of fabrication.

FIGS. 3L-3P are schematic sectional views of different passive interposers that can be utilized in a chip complex at different stages of fabrication.

FIG. 4 is a schematic illustration of an electronic device having a chip package, the chip package having a chip complex.

FIGS. 5-7 are schematic illustrations of different chip complexes that can be utilized in the chip package illustrated in FIG. 4.

FIG. 8 is a block diagram of a method for fabricating a chip complex, the method extendible to form a chip package.

FIGS. 9A-9G are schematic sectional views of a chip complex at different stages of fabrication.

FIG. 10 is a block diagram of a method for fabricating a chip complex, the method extendible to form a chip package.

FIGS. 11A-11F are schematic sectional views of a chip complex at different stages of fabrication.

FIG. 12 is a block diagram of a method for fabricating a chip complex, the method extendible to form a chip package.

FIGS. 13A-13G are schematic sectional views of a chip complex at different stages of fabrication.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Described herein is a chip complex that includes at least a first IC die present in a first common tier, a passive interposer, and a plurality of IC dies present in a second common tier. The chip complex may be utilized in chip packages and electronic devices. The passive interposer of the chip complex includes routing formed in a back end of the line (BEOL) region. Forming the routing in the passive interposer using BEOL process coupled with hybrid bonding between the routing of the passive interposer and the first die disposed in the first common tier, the communication interface between the interposer and IC die is much denser as compared to conventional interposers having build-up layers or rely on conventional bridging dies as discussed above. To further increase the density of interconnects between the passive interposer the IC dies of the second common tier, the plurality of IC dies present in the second common tier are also hybrid bonded to the opposite side of the passive interposer.

The passive interposer is fabricated from a substrate, such as a silicon wafer or other suitable substrate, that includes an interconnect formed on a surface of the substrate. The interconnect is prefabricated on the substrate, for example, using BEOL processes that form patterned metal routings within a plurality of dielectric layers. The interconnect formed in the BEOL layers only includes passive routing, such as not having any transistors. Thus, the passive interposer is a passive routing structure that has no active circuit elements. In some examples, the substrate is thinned and vias are formed through the substrate to connect to the patterned metal routings of the interconnect to the routings formed in the hybrid bonding layer. In other examples, the substrate is completely removed from the BEOL region, leaving the BEOL region to define both sides of the passive interposer. Hybrid bonding layers are formed on both sides of the BEOL region to allow the passive interposer to be packaged using wafer-on-wafer bonding techniques. Wafer-on-wafer bonding provides improved registration between bond pads while also enabling reduced pitch between bond pads. Use of the passive interposer as a middle layer between tiers enables the chip complex to extend beyond reticle limits, making large scale packaging more reliable and cost effective.

In some examples described herein, a chip package is provided that leverages a chip complex having memory dies, such as DRAM, and logic die integration using 3D hybrid bonding. The memory-based chip complex enables high bandwidth and low energy interconnect between the logic and memory dies. By enabling a high bandwidth connection the overall compute performance of the chip package is enhanced. Since many AI applications are memory bound, the memory-based chip complex mitigates this bottleneck for large language model AI chips (training and inference). By reducing the energy consumed in transferring data between the compute engine of compute dies and the memory dies, the memory-based chip complex also improves the performance of chip packages performing AI applications. This energy efficient implementation helps reduce power requirements for large data centers and also enhances performance/watt by allocating more of the available power to improve compute instead of wasting power for data transfer between compute and memory dies. Chip packages having memory-based chip complexes also can be fabricated with reduced processing time by leveraging parallel manufacturing flows by creating partial stacks and combining them to create a multi-tier die stack as the chip complex.

Some advantages of memory-based chip complexes include increased memory bandwidth between memory and logic dies, increased energy efficiency of the chip package by reducing interconnect power consumption, avoiding the need for very large 2.5D chip modules that would be needed to achieve similar performance, reduced manufacturing process time, and avoiding costly process steps for chip-on-wafer assembly by leveraging wafer-on-wafer assembly techniques.

Additionally, the passive interposer of chip complex improves the alignment between interconnects, avoiding the need to design and fabricate TSVs at locations to match the exact interface geometry between logic die and memory die. The use of wafer-on-wafer processes for die stacking reduces the number of expensive process steps involved in chip-on-wafer process, such as gap fill oxide deposition. Moreover, the use of reconstituted wafer with known good IC dies increases product yield. The extensive use of hybrid bonding improves energy efficiency and provides higher bandwidth than traditional 2.5D connections.

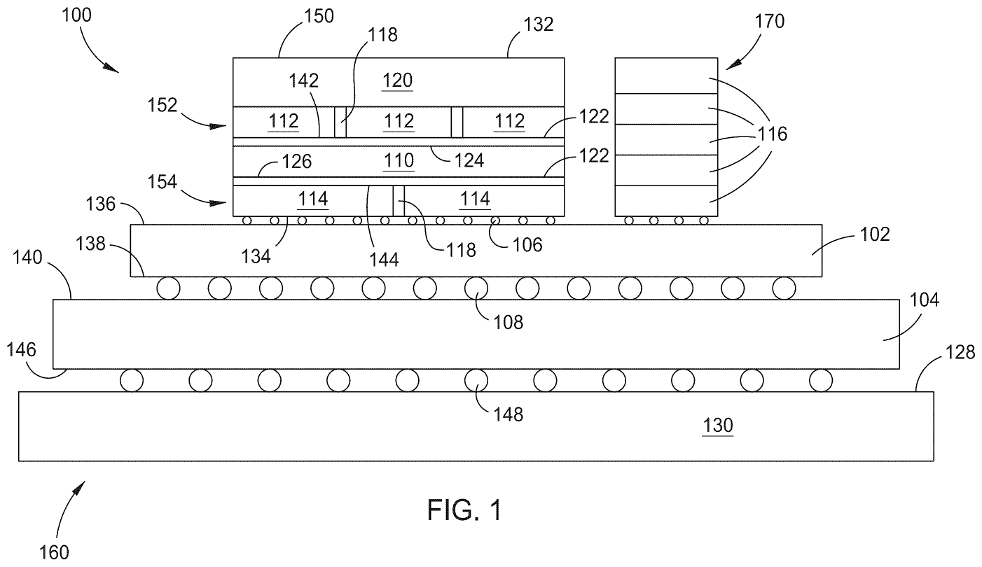

Turning now to FIG. 1, a schematic sectional view of one example of a chip package 100 is provided. The chip package 100 includes at least one integrated circuit (IC) chip complex 150 mounted on one or more substrates. The substrate may be a package substrate 104, or may be a interposer 102 mounted to a package substrate 104. The interposer 102, when present, may have a silicon core with through silicon vias (TSVs), a hybrid silicon-organic interposer such as with an elevated fan-out bridge (EFB), or other suitable interposer. In the example depicted in FIG. 1, the chip package 100 includes at the chip complex 150 mounted on an interposer 102, the interposer 102 mounted on the package substrate 104. The chip package 100 may optionally include one or more additional chip complexes 170 also mounted on the package substrate 104 and/or interposer 102. One additional chip complex 170 is illustrated in FIG. 1. The additional chip complex 170 includes one or IC dies 116.

Any one or all of the IC dies 116 may be a memory IC die, a compute IC die, a phonics IC die or other desired IC die. When configured as a compute die, the IC die 116 includes central processing unit (CPU) cores and/or graphic processing unit (GPU) core. The functional circuitry of the compute dies may also include System Management Unit (SMU) circuitry. The SMU circuitry configured to monitor thermal and power conditions and adjust power and cooling to keep the IC dies 116 functioning as within specifications. The functional circuitry of the compute dies may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition. GPU cores when contained in the functional circuitry of the IC dies 116 generally includes math engine circuitry. The math engine circuitry is generally designed for task specific computing, such as used data center computing, high performance computing and AI/ML computing. Along with the accelerated compute cores, functional circuitry of the IC die 116 may also include SMU circuitry and DFX circuitry.

The chip complex 150 includes a first side 132 and an opposite second side 134. The first side 132 faces away from the interposer 102. The first side 132 may optionally be interface with a thermal management device (not shown in FIG. 1). An example of a thermal management device is a heat sink or a liquid heat exchanger. The second side 134 of the chip complex 150 is coupled to the top surface 136 of the interposer 102 by solder interconnects 106. The solder interconnects 106 may be solder microbumps or other suitable electrical connection suitable for transferring ground, signal and power transmissions between the routing circuitry of the interposer 102 and the functional circuitry of the IC dies within the chip complex 150.

A bottom surface 138 of the interposer 102 may be coupled to a top surface 140 of the package substrate 104. The bottom surface 138 of the interposer 102 is coupled to the top surface 140 of the package substrate 104 by solder interconnects 108 or other suitable interconnect. A bottom surface 146 of the package substrate 104 may be coupled to a top surface 128 of a printed circuit board (PCB) 130, thus forming an electronic device 160. The bottom surface 146 of the package substrate 104 is coupled to the top surface 128 of the PCB 130 by solder interconnects 148, such a ball grid array, or other suitable interconnect. The electronic device 160 may be a tablet, computer, server, data center, call center, automobile on-board electronics system, copier, digital camera, smart phone, control system, automated teller machine, call center, computing system, gaming system, artificial intelligence system, or a machine learning system, among others.

The chip complex 150 includes at least one IC die 112 disposed in a first common tier 152 and a plurality of IC dies 114 disposed in a second common tier 154. The tiers 152, 154 are disposed on opposite sides of the passive interposer 110. The chip complex 150 may optionally include additional tiers of one or more IC dies disposed on one or both sides of the passive interposer 110. The chip complex 150 may also optionally include one or more additional passive interposers 110 disposed between tiers as needed. Dielectric material 118 may be disposed between the IC dies within a common tier to add structural rigidity and reduce the probability of warpage of the chip complex 150. The dielectric material 118 may be may be molding compound, gap fill oxide, or other suitable dielectric material. In one example, the dielectric material 118 is a silicon-based dielectric film, such as SiO or SiN.

The passive interposer 110 is generally at least as wide or wider than at least the IC die 112, which advantageously increased the area available (i.e., beachhead) for signal, ground and power interconnections between the passive interposer 110 and the IC die 112 of the first common tier 152. For example as illustrated in FIG. 1, a first surface 124 of the passive interposer 110 covers an entirety of an adjacent side 142 of the first IC die 112. In some other examples where there are a plurality of IC dies 112 in the first common tier 152, the first surface 124 of the passive interposer 110 covers an entirety of the adjacent sides 142 of at least two of more or even all of the IC dies 112 of the first common tier 152.

Similarly, the passive interposer 110 is at least as wide or wider than at least two or more of the IC dies 114 of the second common tier 154. For example as illustrated in FIG. 1, a second surface 126 of the passive interposer 110 covers an entirety of an adjacent side 144 of at least two of the IC dies 114. In some other examples, the second surface 126 of the passive interposer 110 covers an entirety of the adjacent sides 142 of all of the IC dies 114 of the second common tier 152.

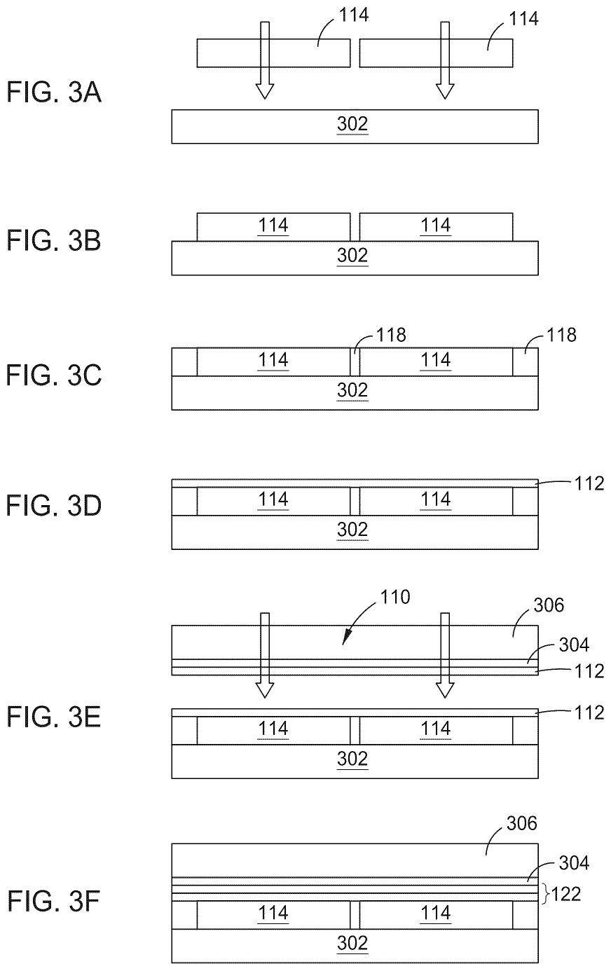

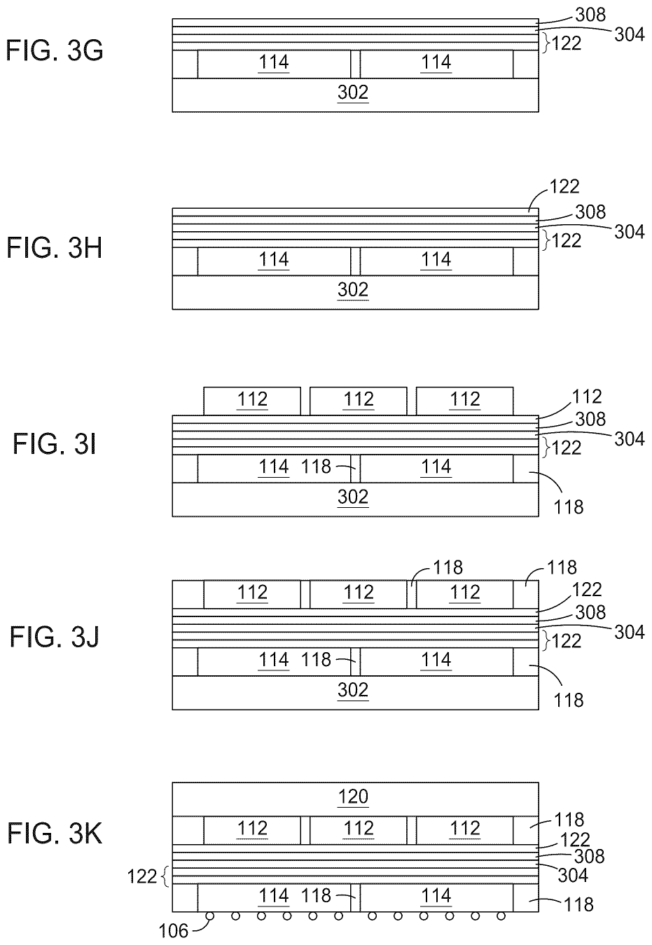

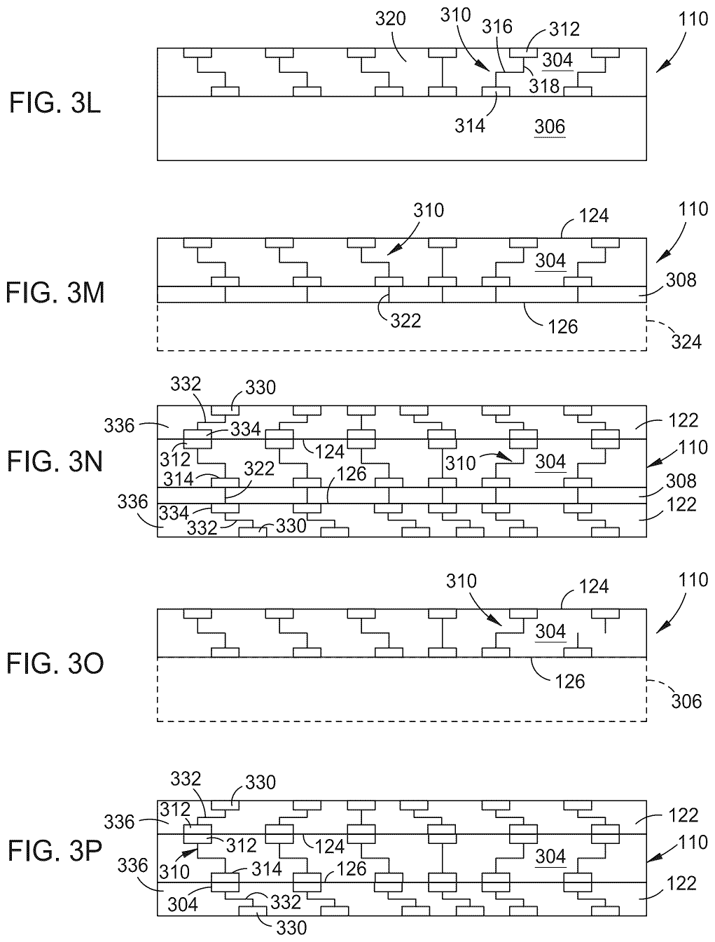

The passive interposer 110, discuss further below with respect to FIG. 3L through FIG. 3P, generally includes at least a back end of the line (BEOL) region that was fabricated in a substrate. The BEOL region may include three to fifteen layers of complex wiring that form the metal interconnect routings that carry the power, ground and signal transmission across the passive interposer. The metal interconnect routings (i.e., circuitry of the passive interposer 110) is generally formed by alternately stacking oxide layers (for insulation purposes) and metal layers (for the interconnect routing). Vias are formed between layers to connect the patterned metal lines to complete the routings. The metal interconnect routings are formed from copper or other good electrical conductor. The interconnect routings terminate at the first surface 124 of the passive interposer 110, on which the hybrid bonding layer 122 is formed for connection with the mating hybrid bonding layer 122 of the first common tier 152. When the substrate is completely removed to leave the BEOL region as the complete passive interposer 110, the opposite ends of the interconnect routings terminate at the second surface 126 of the passive interposer 110, on which the hybrid bonding layer 122 is formed for connection with the mating hybrid bonding layer 122 of the second common tier 154. In examples where the substrate is completely removed after fabrication of the BEOL region, the BEOL region itself defined both of the opposite surfaces 124, 126 of the passive interposer 110 upon which the hybrid bonding layers 122 are formed.

As mentioned above, the hybrid bonding layers 122 physically and electrically couple the adjacent dies 112, 114 of the first and second common tiers 152, 154 to the first and second surfaces 124, 126 of the passive interposer 110. Each hybrid bonding layer 122 includes exposed metal and exposed dielectric material. The exposed metals connected to the circuitries of the structures being connected, such as the functional circuitry of the IC dies and the routings in the BEOL region. Hybrid bonding includes forming non-metal to non-metal bonds, and forming metal-to-metal bonds. The non-metal to non-metal bonds may be formed fusion bonding. The metal-to-metal bonds may be formed using pressure and heat to form eutectic metal bonds. In one example, a hybrid bond is formed by bonding the dielectric materials surrounding the bond pads to first secure the passive interposer 110 and IC dies 112, 114, followed by an interfusion of the metal materials of the bond pads to create the electric interconnect between the functional circuitry of the IC dies 112, 114 and the circuitry (i.e., interconnect routing) of the passive interposer 110. The dielectric materials surrounding the bond pads is selected from a material suitable for hybrid bonding to another dielectric material. Materials that are suitable for hybrid bonding include polybenzoxazole (PBO), polyimide (PI), benzocyclobutene (BCB), a combination thereof, or the like.

Although the first common tier 152 includes at least one IC die 112, the first common tier 152 may optionally include a plurality of IC dies 112. Three IC dies 112 are shown in the example depicted in FIG. 1. Each of the IC dies 112 within the first common tier 152 may include circuitry having the same or different functionality compared to at least one other IC die 112 of the first common tier 152. When one or more additional tiers are stacked on the first common tier 152, the IC dies of the additional tier(s) may include circuitry having the same or different functionality compared to at least one other IC die 112 of the first common tier 152.

The IC die 112 may be configured as a memory IC die, a compute IC die, a phonics IC die or other desired IC die. When configured as a memory die, the IC die 112 includes memory circuitry, such as volatile memory, such as static random-access memory (SRAM), dynamic random-access memory (DRAM) or other suitable volatile memory type. Optionally, the memory circuitry of the IC die 112 may be non-volatile memory, such as ferroelectric random-access memory (FeRAM) and magnetoresistive random-access memory (MRAM) or other suitable non-volatile memory type. When configured as a compute die, the IC die 112 includes CPU cores and/or GPU cores. The functional circuitry of the compute dies may also include SMU circuitry. The SMU circuitry configured to monitor thermal and power conditions and adjust power and cooling to keep the IC dies 112 functioning as within specifications. The functional circuitry of the compute dies may also include DFX Controller IP circuitry. The DFX circuitry provides management of hardware or software trigger events. For example, the DFX circuitry may pull partial bitstreams from memory and delivers them to an ICAP. The DFX circuitry also assists with logical decoupling and startup events, customizable per Reconfigurable Partition. GPU cores when contained in the functional circuitry of the IC die 112 generally includes math engine circuitry. The math engine circuitry is generally designed for task specific computing, such as used data center computing, high performance computing and AI/ML computing. Along with the accelerated compute cores, functional circuitry of the IC die 112 may also include SMU circuitry and DFX circuitry.

One or more of the IC dies 112 may be configured as an active interposer die. An IC die 112 configured as an active interposer die may include memory controller circuity and cache memory circuity. The active interposer die may further include network on a chip (NOC) circuitry; peripheral component interconnect express (PCIe) circuity; memory physical layer (PHY) circuitry configured to communicate with a memory stack; die to die PHY configured to communicate with other IC dies; and I/O PHY configured to communicate with an electronic device remote from the chip package 100.

The IC dies 114 may be configured as described above with reference to the IC dies 112. Each of the IC dies 114 within the second common tier 154 may include circuitry having the same or different functionality compared to at least one other IC die 114 of the second common tier 154. The IC dies 114 may additionally have circuitry having the same or different functionality compared to at least one other IC die 112 of the first common tier 152. One of all of the IC dies 112, 114 may also be optionally be configured as a chiplet.

In one example, one of all of the IC dies 114 comprising the second common tier 154 of IC dies may be logic dies. One of all of the IC dies 112 comprising the first common tier 152 of IC dies may optionally be configured as memory.

The chip complex 150 may optionally include a silicon block 120 mounted to top surfaces of the IC die of the chip complex 150 (shown as the IC dies 112 of the first common tier 152) farthest from the package substrate 104. The silicon block 120 has no functional or routing circuitry, and is utilized so that the total height of the assembled chip complex can be similar to that of a monolithic die, for example, about 800 μm. The silicon block 120 may alternatively or additionally be used to match the height of optional adjacent chip complexes 170 within the chip package 100, provide structural rigidity, and/or to promote good heat transfer out of the chip complex 150.

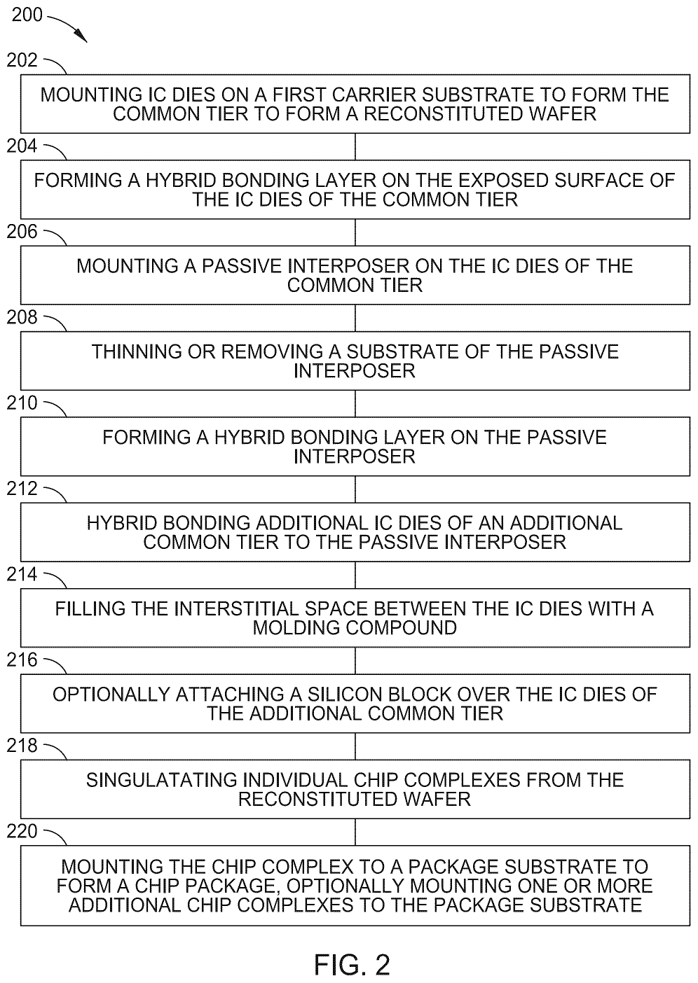

FIG. 2 is a block diagram of a method 200 for fabricating a chip complex, such as the chip complex 150 described above, or other suitable chip complex. The method 200 may be extended to include forming a chip package, such as the chip package 100 described above, or other suitable chip package. FIG. 3A through FIG. 3K depict the chip complex 150 in different stages of fabrication, while FIG. 3L through FIG. 3P depict alternative versions of a passive interposer 110 in different stages of fabrication which may be utilized as the passive interposer 110 in the method 200.

The method 200 begins at operation 202 by mounting IC dies 114 on a first carrier substrate 302 to form the second common tier 154, as illustrated in FIGS. 3A-3B. The IC dies 114 may be mounted on the first carrier substrate 302 using die attach tape, diffusing bonding or other suitable mounting technique. In one example, the carrier substrate 302 is coupled to the backsides of the IC dies 114 to forming the second common tier 154, such that the active side of the IC dies 114 face away from the carrier substrate 302. The second common tier 154 of IC dies 114 bonded to the carrier substrate 302 generally form a reconstituted wafer.

Operation 202 may include depositing dielectric material 118 in the interstitial space between the IC dies 114, as illustrated in FIG. 3C. The dielectric material 118 may be a gap fill oxide or other suitable dielectric material. In one example, the dielectric material 118 is a silicon-based dielectric material, such as SiO, SiN and the like. The carrier substrate 302 may extend beyond the outer sides of the outermost IC dies 114 within the second common tier 154 so that the dielectric material 118 is also disposed laterally outward of the outermost IC dies 114 of the tier 154.

At operation 204, a hybrid bonding layer 122 is formed on the exposed surface of the IC dies 114 of the second common tier 154, as illustrated by FIG. 3D. As discussed above, the hybrid bonding layer 122 includes exposed metal pads and exposed dielectric material. The exposed metal pads are connected to the bond pad exposed on the adjacent side 144 of the IC dies 114 by vias and lines forming the routing within the hybrid bonding layer 122. The bond pads are connected to the functional circuitry of the IC dies 114.

At operation 206, the passive interposer 110 is mounted to the IC dies 114 of the second common tier 154, as illustrated in FIGS. 3E and 3F. The passive interposer 110 may be mounted to the IC dies 114 of the second common tier 154 using wafer-to-wafer mounting or other techniques. In one example, the IC dies 114 of the second common tier 154 are hybrid bonded to the passive interposer 110. The passive interposer 110 includes a BEOL region 304 fabricated on a substrate 306. The substrate 306 may be a silicon or other type of wafer on which a routing interconnect may be formed using BEOL techniques. The BEOL techniques used to form the routing interconnect results in routing densities to 20 nm pitch and below.

At operation 208, the substrate 306 of the passive interposer 110 is thinned to form a thinned interposer 308, as illustrated in FIG. 3G. The substrate 306 may be thinned to less than 50% or even less than 10% of the substrate's 308 pre-thinning original thickness. The substrate 306 may be thinned by grinding, etching, milling or other suitable technique. The substrate 306 may be optionally be completely removed, leaving only the BEOL region 304 as the thinned interposer 308.

Referring now to FIG. 3L through FIG. 3P, addition details of the thinning of the substrate 306 performed at operation 208 are provided. As illustrated in FIG. 3L, the passive interposer 110 includes a BEOL region 304 formed on a substrate 306. The BEOL region 304 includes interconnect routings 310 formed form patterned metal layers that form lines 316 and vias 318 in dielectric layers 320. There are no transistors or other active circuitry in the BEOL region 304. The routings 310 connect to bond pads 312, 314 formed on opposite sides of the BEOL region 304. The bond pads 312 are later connected to bond pads formed in the hybrid bonding layer 122 while the bond pads 314 are later connected to bond pads formed in the hybrid bonding layer 122 disposed on the opposite side of the passive interposer 110 or vias 322 formed through the substrate 306.

After forming the BEOL region 304, the substrate 306 is either thinned or removed entirely. FIG. 3M illustrates a version of the passive interposer 110 where the substrate 306 is removed entirely. As illustrated in FIG. 3M, the substrate 306 has been thinned by removing the portion 324 of the substrate 306 shown in phantom to form a thinned substrate 308. The thinned substrate 308 includes through silicon vias (TSVs) that connect to the bond pads 312 formed in the BEOL region 304. The exposed surface of the BEOL region 304 forms the first surface 124 of the completed passive interposer 110, while the exposed surface of the thinned substrate 308 forms the second surface 126 of the completed passive interposer 110.

Subsequently, the hybrid bonding layers 122 are formed on the first surface 124 and the second surface 126 of the passive interposer 110, as illustrated in FIG. 3N. It should be noted that one of the hybrid bonding layers 122 may be formed on the passive interposer 110 after the passive interposer 110 has been hybrid bonded to a neighboring structure using the other of the hybrid bonding layers 122.

Each of the hybrid bonding layers 122 illustrated in FIG. 3N includes routing 332 formed from patterned lines and via. The routing 332 terminate at bond pads 330, 334, such are formed from copper or other suitable material. The patterned lines and via of the routing 332 are electrically isolated from one another by a plurality of dielectric layers 336. The dielectric layers 336 are formed from a material suitable for hybrid bonding, such as polybenzoxazole (PBO), polyimide (PI), benzocyclobutene (BCB), a combination thereof, or the like.

When the hybrid bonding layer 122 is placed in contact with another hybrid bonding layer 122, the exposed dielectric layer 336 of one hybrid bonding layer 122 fusion bonds to the exposed dielectric layer 336 of the other hybrid bonding layer 122, combining the two hybrid bonding layers 122 to form a single hybrid bonding layer 122 that holds the bonded structures together. Subsequently, the metal-to-metal bonds may be formed using pressure and heat to form eutectic metal bonds between the bond pads 330 now in contact with each other within the combined hybrid bonding layer 122. The interfusion of the metal materials of the bond pads 330 to create the electric interconnect between the routing of the passive interposer 110 and the functional circuitry of the IC dies being bonded to the passive interposer 110.

FIG. 3O illustrates a version of the passive interposer 110 where the substrate 306 is removed entirely. As illustrated in FIG. 3O, the substrate 306 is completely removed as shown in phantom, leaving only the BEOL region 304 as the entire passive interposer 110.

Subsequently, the hybrid bonding layers 122 are formed on the first surface 124 and the second surface 126 of the passive interposer 110 that are now defined by the opposite sides of the BEOL region 304. On the second surface 126 of the passive interposer 110, the bond pads 334 of the routing 332 are formed on the exposed bond pads 314 of the routing 310, as illustrated in FIG. 3P. At this point, the passive interposer 110 is ready for hybrid bonding to an adjacent structure (such as the dies 112, 114 of the adjacent common tiers 152, 154).

Referring back to FIG. 2, a hybrid bonding layer 122 is formed on the passive interposer 110 at operation 210 and as illustrated in FIG. 3H. Although the passive interposer 110 illustrated in FIG. 3H includes a thinned substrate (308 as illustrated in FIG. 3M), the passive interposer 110 may alternatively have the substrate 306 and comprise solely the BEOL region 304 (as illustrated in FIG. 3O).

At operation 212, the IC dies 112 of the first common tier 152 are hybrid bonded to the passive interposer 110, as illustrated in FIG. 3I. At operation 214, the interstitial space between the IC dies 112 may be filled using a dielectric material 118, as illustrated in FIG. 3J. At optional operation 216, an optional silicon block 120 may be disposed over the IC dies 112 of the first common tier 152, as illustrated in FIG. 3K. The silicon block 120 may be attached to IC dies 112 of the first common tier 152 by fusion bonding, die attach tape, adhesive, or other suitable technique.

The method 200 continues at operation 218 by singulatating the individual chip complexes 150 from the reconstituted wafer. Each chip complex 150 can be sold and shipped as a unit to another fabricator who would utilized the chip complex 150 to fabricate a chip package 100. If chip complexes 150 are the desired end product, the method 200 may end after singulatation. If a chip package 100 is the desired end product, the method 200 continues at operation 220 by mounting the chip complex 150 to the interposer 102 (or alternatively directly to the package substrate 104) utilizing the solder connections 106 or through another suitable technique to form the chip package 100. Optionally at operation 220, one or more additional chip complexes 170 may be mounted to the interposer 102 (or alternatively directly to the package substrate 104). Also optionally at operation 220, the chip package 100 may be mounted to the PCB 130 to form the electronic device 160.

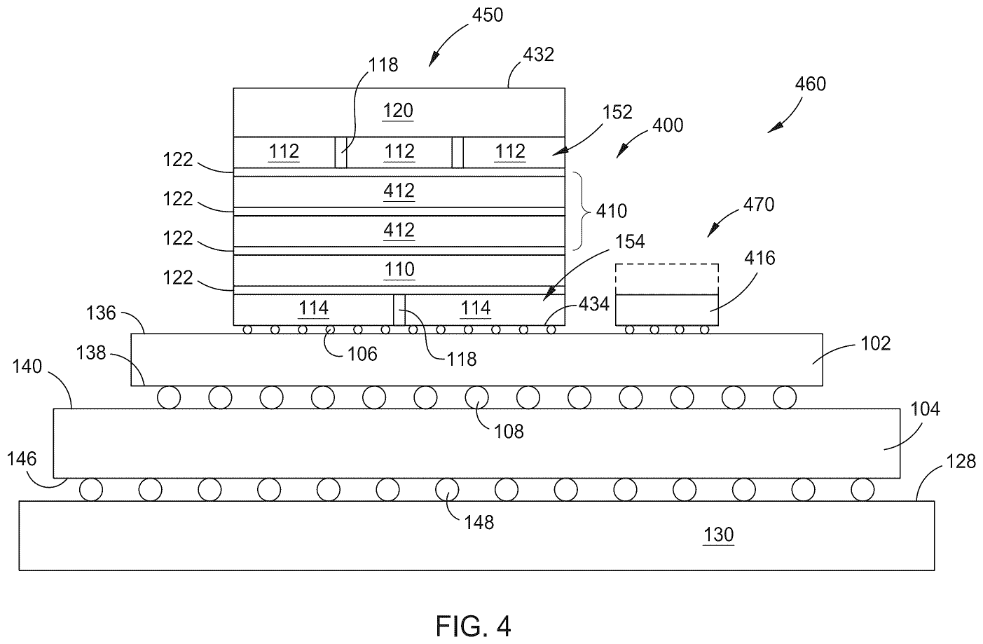

FIG. 4 is a schematic sectional view of another example of a chip package 400. The chip package 400 may be configured as a memory device, such as a high bandwidth memory (HBM) device. The chip package 400 includes at least one integrated circuit (IC) chip complex 450 configured as a memory device and at least one chip complex 470 configured as a logic device both mounted on an interposer 102 (or alternatively directly to the package substrate 104). The chip complex 450 utilizes the same passive interposer 110 disposed between two tiers of IC dies as described above. The chip package 400 may optionally include one or more additional chip complexes 450, 470 also mounted on the interposer 102 (or alternatively directly to the package substrate 104).

The chip complex 450 includes one or more IC dies 112 configured as compute dies. The IC die 112 includes central processing unit (CPU) cores and/or graphic processing unit (GPU) core. The functional circuitry of the compute dies may also include System Management Unit (SMU) circuitry. The SMU circuitry configured to monitor thermal and power conditions and adjust power and cooling to keep the IC dies 112 functioning as within specifications. The functional circuitry of the compute dies may also include Dynamic Function eXchange (DFX) Controller IP circuitry, The DFX circuitry provides management of hardware or software trigger events. For example, the DFX circuitry may pull partial bitstrearns from memory and delivers them to an internal configuration access port (CAP). The DFX circuitry also assists with logical decoupling and startup events, customizable per Reconfigurable Partition. GPU cores when contained in the functional circuitry of the IC dies 112 generally includes math engine circuitry. The math engine circuitry is generally designed for task specific computing, such as used data center computing, high performance computing and AI/ML computing. Along with the accelerated compute cores, functional circuitry of the IC die 112 may also include SMU circuitry and DFX circuitry. The IC dies 112 communicate with memory circuits of the chip complex 450 through routing formed in or on the interposer 102

The chip complex 450 includes a first side 432 and an opposite second side 434. The first side 432 faces away from the package substrate 104. The first side 432 may optionally be interface with a thermal management device (not shown in FIG. 4). The second side 434 of the chip complex 450 is coupled to the top surface 136 of the interposer 102 by solder interconnects 106 (or in instances where the interposer 102 is not utilized, to the top surface 140 of the package substrate 104).

A bottom surface 138 of the interposer 102 may be coupled to a top surface 140 of the package substrate 104. The bottom surface 138 of the interposer 102 is coupled to the top surface 140 of the package substrate 104 by solder interconnects 108 or other suitable interconnect. A bottom surface 146 of the package substrate 104 may be coupled to a top surface 128 of a printed circuit board (PCB) 130, thus forming an electronic device 460. The bottom surface 146 of the package substrate 104 is coupled to the top surface 128 of the PCB 130 by solder interconnects 148, such a ball grid array, or other suitable interconnect. The electronic device 460 any of the devices described above with reference to the electronic device 160.

The chip complex 450 includes a memory stack 410, at least one IC die 112 disposed in a first common tier 152 and at plurality of IC dies 114 disposed in a second common tier 154. The tiers 152, 154 are disposed on opposite sides of the passive interposer 110. The chip complex 150 may optionally include additional tiers of one or more IC dies disposed on one or both sides of the passive interposer 110. The chip complex 150 may also optionally include one or more additional passive interposers 110 disposed between tiers as needed. Dielectric material 118 may be disposed between the IC dies within a common tier to add structural rigidity and reduce the probability of warpage of the chip complex 150.

The memory stack 410 comprises a stack of one or more memory IC dies 412. Although two memory IC dies 412 are shown in the memory stack 410 illustrated in FIG. 4, the memory stack 410 may include 4, 5, 6, 7, 8 or more memory IC dies 412 stacked in a single column. Alternatively, the memory IC dies 412 may be stacked in two or more columns where the width of a row of memory IC dies 412 across multiple columns do not exceed the width of the passive interposer 110. The memory IC dies 412 are secured together within the memory stack 410 by hybrid bonding, for example, by using a hybrid bonding layer 122 deposed between adjacent memory IC dies 412. Each memory IC die 412 includes memory circuitry, such as volatile memory, such as static random-access memory (SRAM), dynamic random-access memory (DRAM) or other suitable volatile memory type. Optionally, the memory circuitry of the memory IC die 412 may be non-volatile memory, such as ferroelectric random-access memory (FeRAM) and magnetoresistive random-access memory (MRAM) or other suitable non-volatile memory type.

The memory IC dies 412 communicate with the compute dies 112 of the chip complex 470 through the interposer 102. The memory controller circuit may reside on one of the IC dies 114, 112 of the chip complex 450, or within one of the compute dies 112 of the chip complex 470. In one example, the memory controller circuitry resides on at least one of the IC dies 114 which is configured as an active interposer die, while at least one of the IC dies 112 is configured as a compute die.

The passive interposer 110 is generally at least as wide or wider than at least the memory IC die 142 which advantageously increased the area available (i.e., beachhead) for signal, ground and power interconnections. For example as illustrated in FIG. 4, a first surface 124 of the passive interposer 110 covers an entirety of an adjacent side 442 of the memory IC die 412. Also as illustrated in FIG. 4, a second surface 126 of the passive interposer 110 covers an entirety of one of the IC dies 114 disposed in the second common tier 154 adjacent the passive interposer 110. In some other examples where there are a plurality of IC dies 114 in the second common tier 154, the second surface 126 of the passive interposer 110 covers an entirety of at least two of more or even all of the IC dies 114 of the second common tier 154. The passive interposer 110 may be consist solely of routing formed in a BEOL region, or may additionally include a thinned substrate with TSVs.

As mentioned above, the hybrid bonding layers 122 physically and electrically couple the IC dies 112, 114, 412 to each other IC dies of the chip complex 450 and/or to the passive interposer 110. In the example depicted in FIG. 4, the IC dies 114 of the second common tier 154 are hybrid bonded utilizing a hybrid bonding layer 122 to the passive interposer 110, the passive interposer 110 is hybrid bonded utilizing a hybrid bonding layer 122 to the memory stack 410, and the memory stack 410 is hybrid bonded to the IC dies 112 of the first common tier 152 utilizing a hybrid bonding layer 122. The optional silicon block 120 may be fusion bonded or otherwise secured to the IC dies 112 of the first common tier 152.

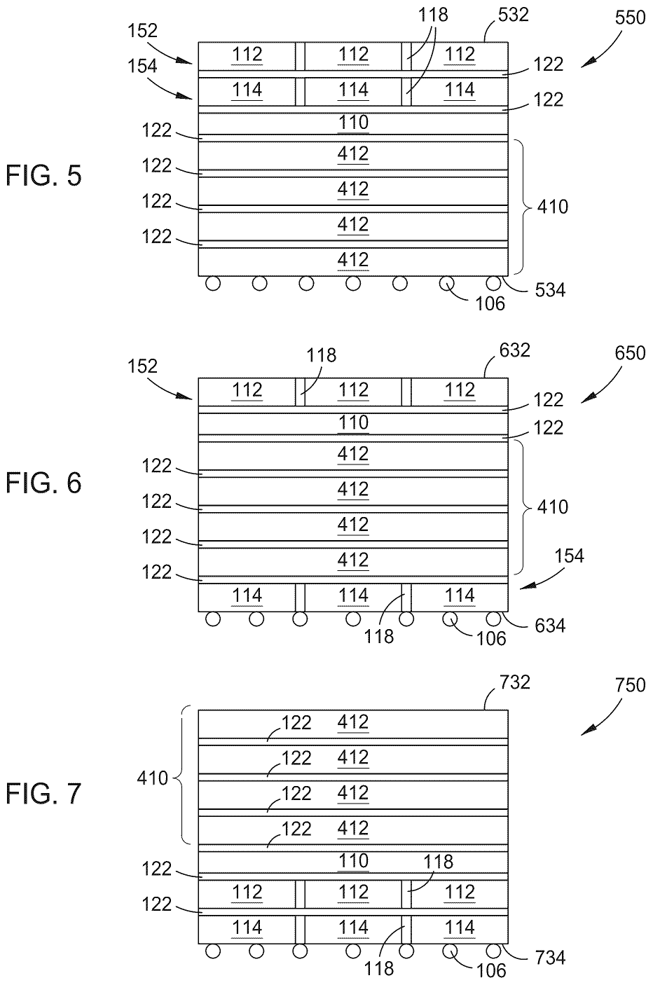

FIGS. 5-7 are schematic illustrations of different chip complexes 550, 650, 750 that can be utilized in the chip package 400 illustrated in FIG. 4 in place of the chip complex 450. The chip complexes 550, 650, 750 are generally the same as the chip complex 450, except that the memory stack 410, the first common tier 152 of IC dies 112, and the second common tier 154 of IC dies 114 have different locations within the chip complex.

Turning first to the chip complex 550 illustrated in FIG. 5, the chip complex 550 includes at least one or more passive interposers 110, two or more IC dies 112 of a first common tier 152, and two or more IC dies 114 of a second common tier 154. The chip complex 750 has a first side 532 and a second side 534. The second side 534 is configured to mount on the package substrate 104 and/or interposer 102 utilizing solder interconnects 108/106. The chip complex 550 includes a memory stack 410 comprising one or more memory IC dies 412. Four memory IC dies 412 are shown in FIG. 5, although between 1 and 8 or more memory IC dies 412 may alternatively be utilized. The IC dies 412 are hybrid bonded together, for example by using a hybrid bonding layer 122. Additional details of the memory stack 410 are described above with reference to FIG. 4.

Continuing to refer to FIG. 5, one side of the memory stack 410 defines the second side 534 of the chip complex 550. The side of the memory stack 410 is hybrid bonded utilizing a hybrid bonding layer 122 to the passive interposer 110. The passive interposer 110 is hybrid bonded utilizing a hybrid bonding layer 122 to the IC dies 114 of the second common tier 154. The IC dies 114 of the second common tier 154 are hybrid bonded utilizing a hybrid bonding layer 122 to the IC dies 112 of the first common tier 152. The optional silicon block 120 may be fusion bonded or otherwise secured to the IC dies 112 of the first common tier 152.

FIG. 6 depicts another example of a chip complex 750. The chip complex 650 has a first side 632 and a second side 634. The second side 634 is configured to mount on the package substrate 104 or interposer 102 utilizing solder interconnects 108/106. The chip complex 650 includes a memory stack 410 comprising one or more memory IC dies 412. Four memory IC dies 412 are shown in FIG. 6, although between 1 and 8 or more memory IC dies 412 may alternatively be utilized. The IC dies 412 are hybrid bonded together, for example by using a hybrid bonding layer 122.

The chip complex 650 includes at least one or more passive interposers 110, two or more IC dies 112 of a first common tier 152, and two or more IC dies 114 of a second common tier 154. One side of the IC dies 114 of the second common tier 154 define the second side 634 of the chip complex 650. The other side of the IC dies 114 of the second common tier 154 are hybrid bonded utilizing a hybrid bonding layer 122 to the memory stack 410. The memory stack 410 is hybrid bonded utilizing a hybrid bonding layer 122 to the IC dies 112 of the first common tier 152. The optional silicon block 120 may be fusion bonded or otherwise secured to the IC dies 112 of the first common tier 152.

FIG. 7 depicts another example of a chip complex 750. The chip complex 750 has a first side 732 and a second side 734. The second side 734 is configured to mount on the optional interposer 102 or the package substrate 104 utilizing solder interconnects 106/108. The chip complex 750 includes a memory stack 410 comprising one or more memory IC dies 412. Four memory IC dies 412 are shown in FIG. 7, although between 1 and 8 or more memory IC dies 412 may alternatively be utilized. The IC dies 412 are hybrid bonded together, for example by using a hybrid bonding layer 122.

The chip complex 750 includes at least one or more passive interposers 110, two or more IC dies 112 of a first common tier 152, and two or more IC dies 114 of a second common tier 154. One side of the IC dies 114 of the second common tier 154 define the second side 734 of the chip complex 750. The other side of the IC dies 114 of the second common tier 154 are hybrid bonded utilizing a hybrid bonding layer 122 to the IC dies 112 of the first common tier 152. The IC dies 112 of the first common tier 152 are hybrid bonded utilizing a hybrid bonding layer 122 to the memory stack 410. The optional silicon block 120 (not shown in FIG. 7) may be fusion bonded or otherwise secured to a side of the memory stack 410 opposite the first common tier 152.

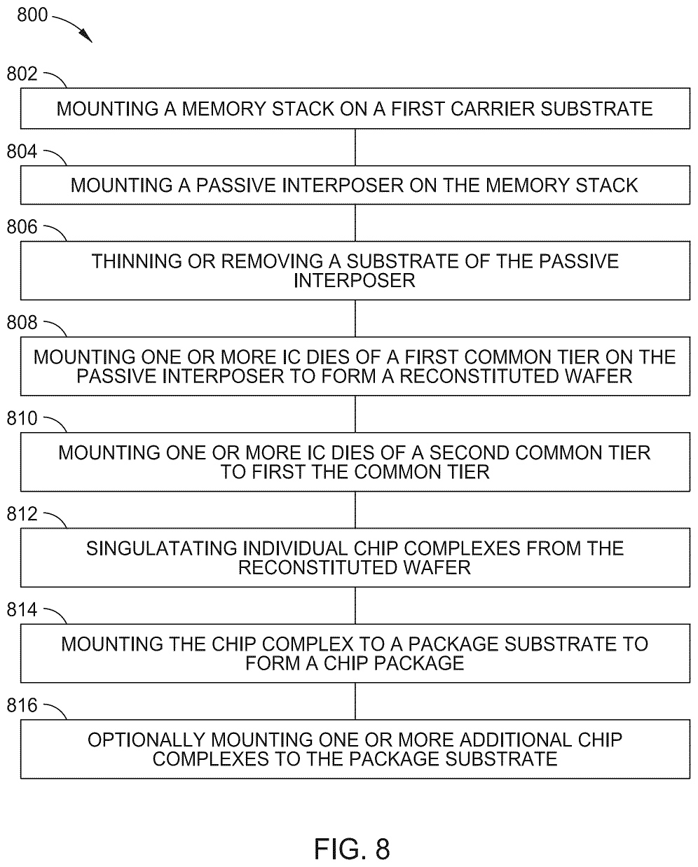

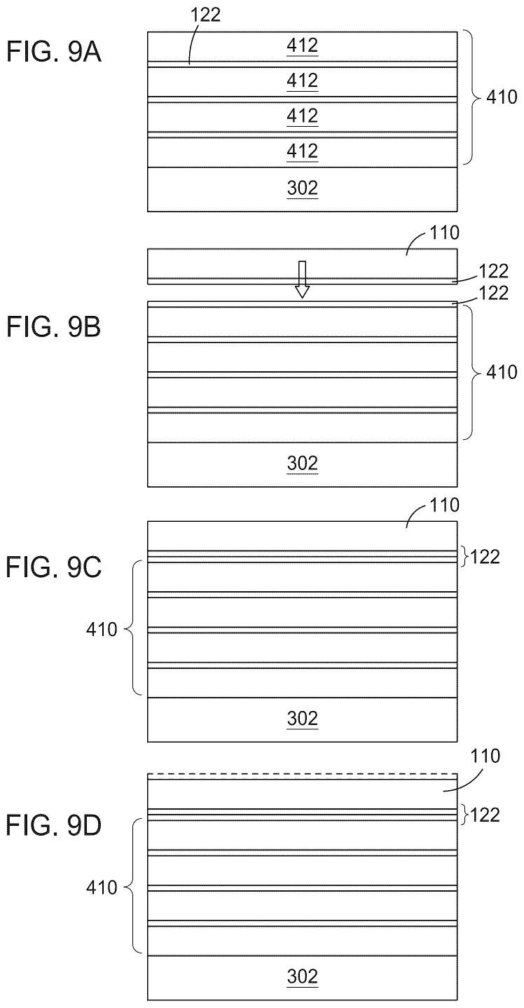

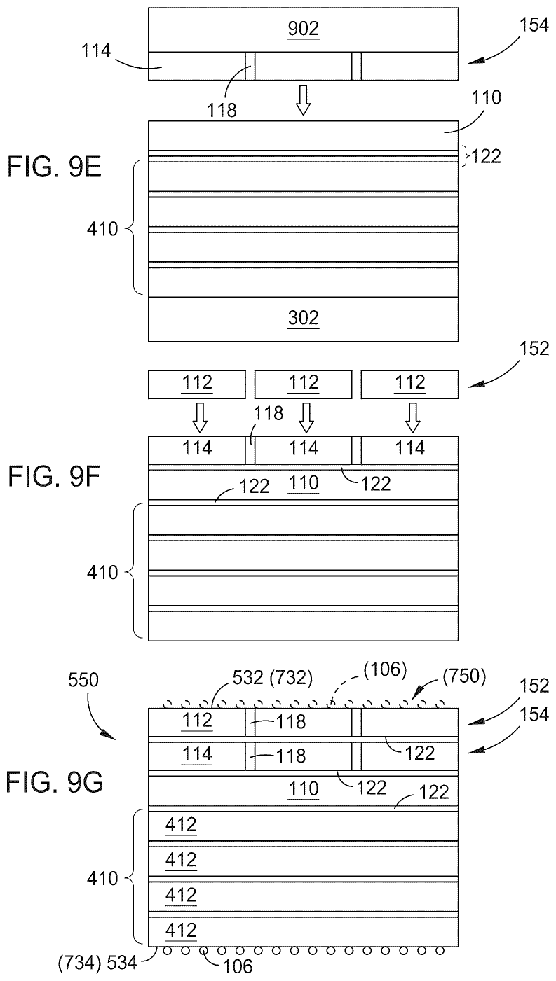

FIG. 8 is a block diagram of a method 800 for fabricating a chip complex, such as the chip complex 550, 750 or other similar chip complex. The method 800 may be extended to form a chip package, such as the chip package 400, or other suitable chip package. FIG. 9A through FIG. 9G depict the chip complex 550 (750) in different stages of fabrication.

The method 800 begins at operation 802 by mounting a memory stack 410 on a first carrier substrate 302, as illustrated in FIGS. 9A. The memory stack 410 may be mounted on the first carrier substrate 302 using die attach tape, diffusing bonding or other suitable mounting technique. As discussed above, the memory stack 410 includes one or more memory IC dies 412. Although four memory IC dies 412 are shown in the memory stack 410 illustrated in FIG. 9A, the memory stack 410 may include 4, 5, 6, 7, 8 or more memory IC dies 412 stacked in a single column. Alternatively, the memory IC dies 412 may be stacked in two or more columns. The memory IC dies 412 are secured together within the memory stack 410 by hybrid bonding, for example, by using a hybrid bonding layer 122 deposed between adjacent memory IC dies 412.

At operation 804, the passive interposer 110 is mounted to the memory stack 410, as illustrated in FIGS. 9B and 9C. The passive interposer 110 may be mounted to the memory stack 410 using wafer-to-wafer mounting or other techniques. In one example, the memory stack 410 are hybrid bonded to the passive interposer 110, for example, by using a hybrid bonding layer 122. As described above, the passive interposer 110 includes a BEOL region 304 fabricated on a substrate 306. The substrate 306 may be a silicon or other type of wafer on which a routing interconnect may be formed using BEOL techniques. The BEOL techniques used to form the routing interconnect results in routing densities to 80 nm pitch and below.

At operation 806, the substrate 306 of the passive interposer 110 is thinned to form a thinned interposer 308, as illustrated in FIG. 9D. The substrate 306 may be thinned to less than 50% or even less than 10% of the substrate's 308 pre-thinning original thickness. The substrate 306 may be thinned by grinding, etching, milling or other suitable technique. The substrate 306 may be optionally be completely removed, leaving only the BEOL region 304 as the thinned interposer 308.

At operation 808, one or more IC dies 114 are mounted to the passive interposer 110, as illustrated in FIG. 9E. The IC dies 114 may be arranged in a common tier 154 prior to mounting on the passive interposer 110, for example by forming a reconstituted wafer using a carrier substrate 902 with dielectric material 118 disposed between adjacent IC dies 114. The IC dies 114 may be secured to the carrier substrate 902 by fusing bonding, die attached tape, or other suitable technique. Although not illustrated in FIG. 9E, the IC dies 114 are secured to the passive interposer 110 using hybrid bonding, for example, by using a hybrid bonding layer 122.

At operation 810, one or more IC dies 112 are mounted to the common tier 154 of IC dies 114, as illustrated in FIG. 9F. The IC dies 112 may be arranged in a common tier 152. The IC dies 112 of the common tier 152 may be secured to the IC dies 114 of the common tier 154 by using hybrid bonding, for example, by using a hybrid bonding layer 122. Once the IC dies 112 are mounted to the common tier 154 of IC dies 114, the interstitial space between the IC dies 112 is filled with dielectric material 118.

The chip complex 550 may finished by disposing solder interconnects 106 on the memory IC die 412 forming the second side 534 of the chip complex 550. Alternatively, the chip complex 750 may finished by disposing solder interconnects 106 on the common tier 154 of IC dies 112 forming the second side 734 of the chip complex 750.

The method 800 continues at operation 812 by singulatating the individual chip complexes 550 (750) from the reconstituted wafer. Each chip complex 550 (750) can be sold and shipped as a unit to another fabricator who would utilized the chip complex 550 (750) to fabricate a chip package 400. If chip complexes 550 (750) are the desired end product, the method 800 may end after singulatation. If a chip package 400 is the desired end product, the method 800 continues at operation 814 by mounting the chip complex 550 (750) to the optional interposer 102 and the package substrate 104 utilizing the solder connections 106/108 or through another suitable technique to form the chip package 400. Optionally at operation 816, one or more additional chip complexes 470 may be mounted to the interposer 102 and/or package substrate 104. Also optionally at operation 816, the chip package 400 may be mounted to the PCB 130 to form the electronic device 460.

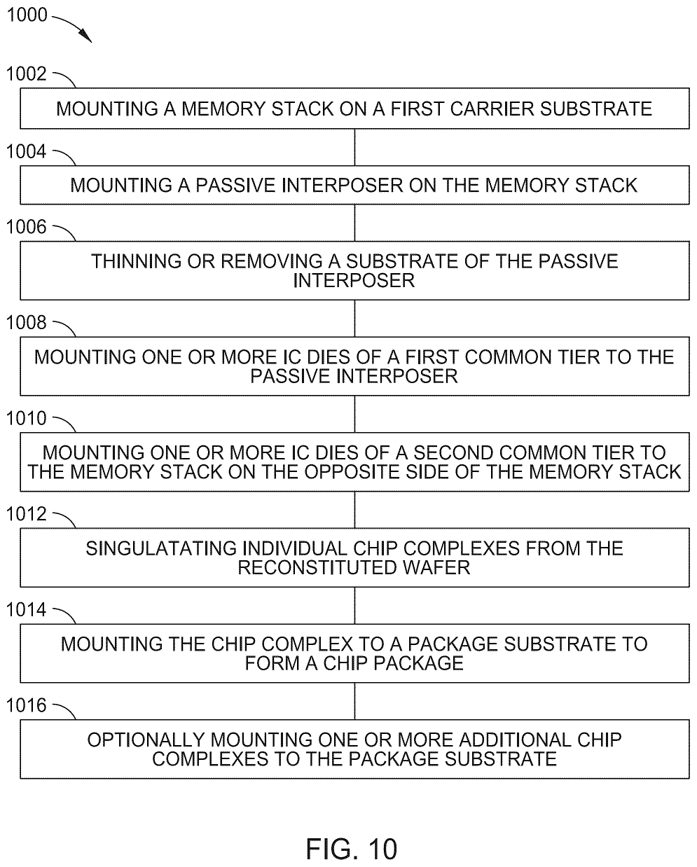

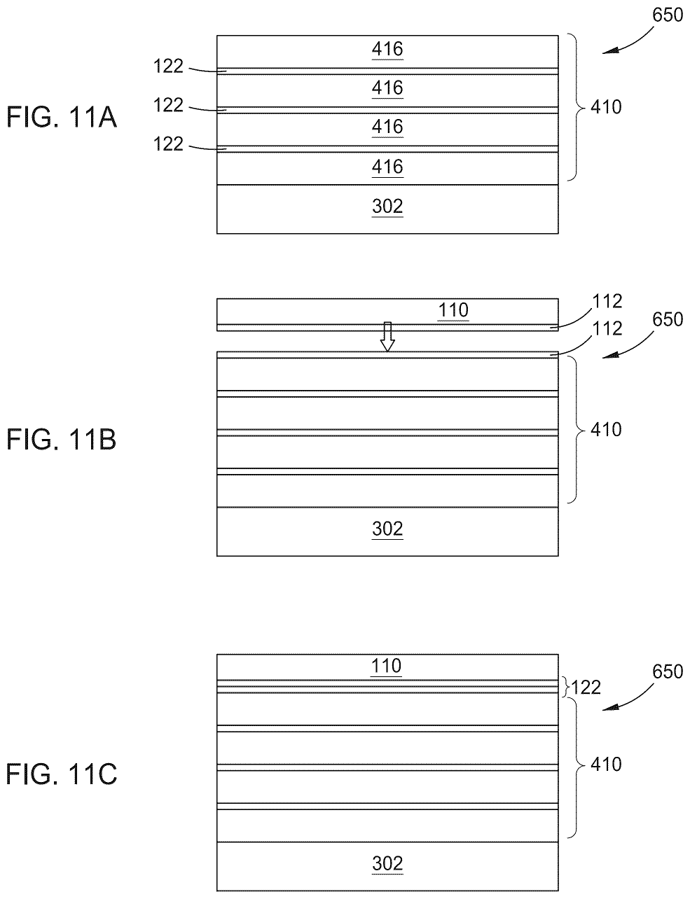

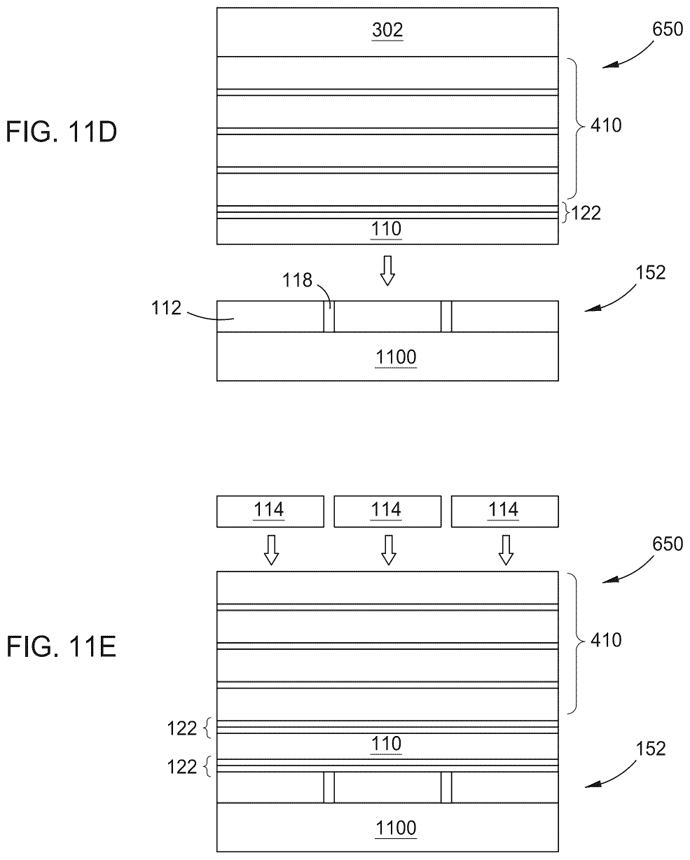

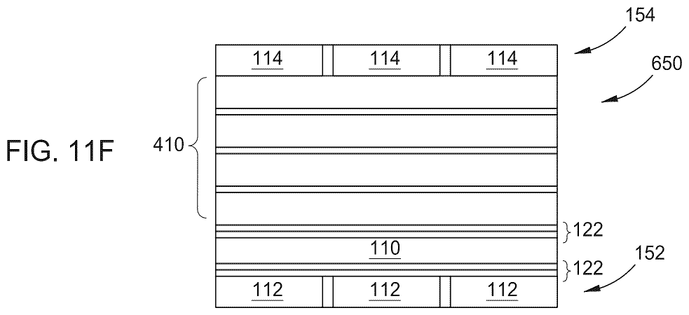

FIG. 10 is a block diagram of a method 1000 for fabricating a chip complex, such as the chip complex 650 or other similar chip complex. The method 1000 may be extended to form a chip package, such as the chip package 400, or other suitable chip package. FIG. 11A through FIG. 11F depict the chip complex 650 in different stages of fabrication.

The method 1000 begins at operation 1002 by mounting a memory stack 410 on a first carrier substrate 302, as illustrated in FIGS. 11A. The memory stack 410 may be mounted on the first carrier substrate 302 using die attach tape, diffusing bonding or other suitable mounting technique. As discussed above, the memory stack 410 includes one or more memory IC dies 412. Although four memory IC dies 412 are shown in the memory stack 410 illustrated in FIG. 11A, the memory stack 410 may include 4, 5, 6, 7, 10 or more memory IC dies 412 stacked in a single column. Alternatively, the memory IC dies 412 may be stacked in two or more columns. The memory IC dies 412 are secured together within the memory stack 410 by hybrid bonding, for example, by using a hybrid bonding layer 122 deposed between adjacent memory IC dies 412.

At operation 1004, the passive interposer 110 is mounted to the memory stack 410, as illustrated in FIG. 11B. The passive interposer 110 may be mounted to the memory stack 410 using wafer-to-wafer mounting or other techniques. In one example, the memory stack 410 are hybrid bonded to the passive interposer 110, for example, by using a hybrid bonding layer 122. As described above, the passive interposer 110 includes a BEOL region 304 fabricated on a substrate 306. The substrate 306 may be a silicon or other type of wafer on which a routing interconnect may be formed using BEOL techniques. The BEOL techniques used to form the routing interconnect results in routing densities to 100 nm pitch and below.

At operation 1006, the substrate 306 of the passive interposer 110 is thinned to form a thinned interposer 308, as illustrated in FIG. 11C. The substrate 306 may be thinned to less than 50% or even less than 10% of the substrate's 308 pre-thinning original thickness. The substrate 306 may be thinned by grinding, etching, milling or other suitable technique. The substrate 306 may be optionally be completely removed, leaving only the BEOL region 304 as the thinned interposer 308.

At operation 1008, one or more IC dies 112 are mounted to the passive interposer 110, as illustrated in FIG. 11D. The IC dies 112 may be arranged in a common tier 152 prior to mounting on the passive interposer 110, for example by forming a reconstituted wafer using a carrier substrate 1100 with dielectric material 118 disposed between adjacent IC dies 112. The IC dies 112 may be secured to the carrier substrate 1100 by fusing bonding, die attached tape, or other suitable technique. Although not illustrated in FIG. 11D, the IC dies 112 are secured to the passive interposer 110 using hybrid bonding, for example, by using a hybrid bonding layer 122.

At operation 1010, one or more IC dies 114 are mounted to the memory stack 410 on the opposite side of the memory stack 410 from the common tier 152 of IC dies 112, as illustrated in FIG. 11E. The IC dies 114 may be arranged in a common tier 154. The IC dies 114 of the common tier 154 may be secured to the exposed memory IC die 412 of the memory stack 410 by using hybrid bonding, for example, by using a hybrid bonding layer 122 (not shown in FIG. 11E). Once the IC dies 114 are mounted to the memory stack 410, the interstitial space between the IC dies 114 is filled with dielectric material 118, as illustrated in FIG. 11F.

The method 1000 continues at operation 1012 by singulatating the individual chip complexes 650 from the reconstituted wafer. Each chip complex 650 can be sold and shipped as a unit to another fabricator who would utilized the chip complex 650 to fabricate a chip package 400. If chip complexes 650 are the desired end product, the method 1000 may end after singulatation. If a chip package 400 is the desired end product, the method 1000 continues at operation 1014 by mounting the chip complex 650 to the interposer 102 and/or package substrate 104 utilizing the solder connections 106/108 or through another suitable technique to form the chip package 400. Optionally at operation 1016, one or more additional chip complexes 470 may be mounted to the interposer 102 (or alternatively, the package substrate 104). Also optionally at operation 1016, the chip package 400 may be mounted to the PCB 130 to form the electronic device 460.

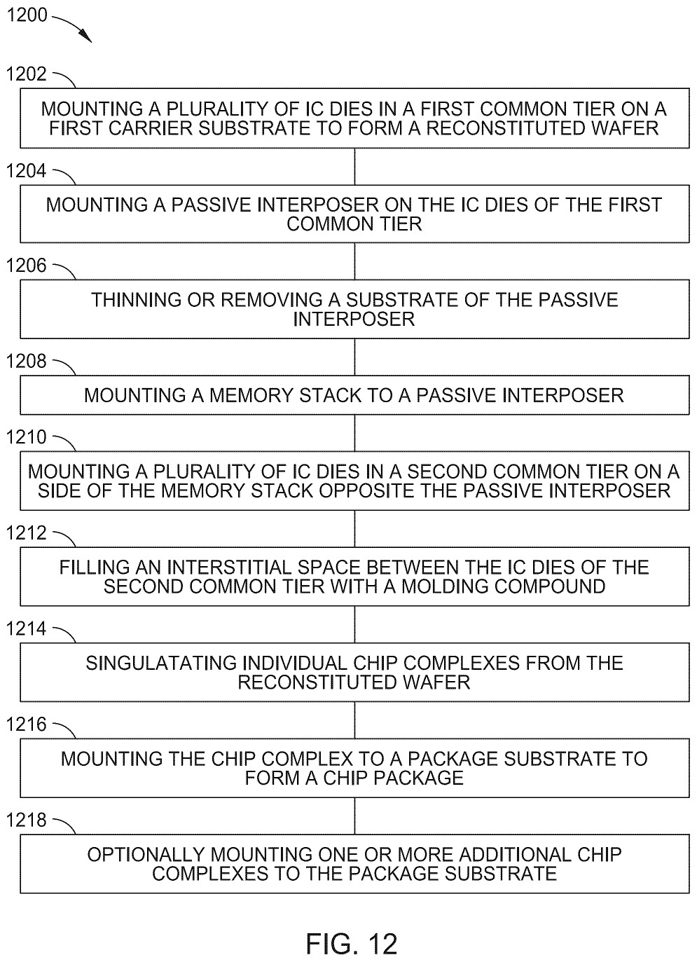

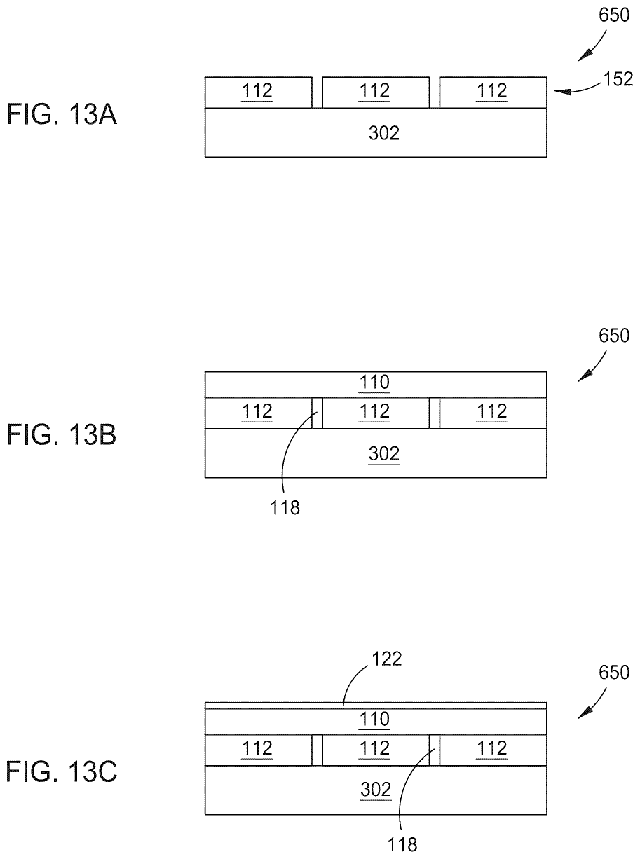

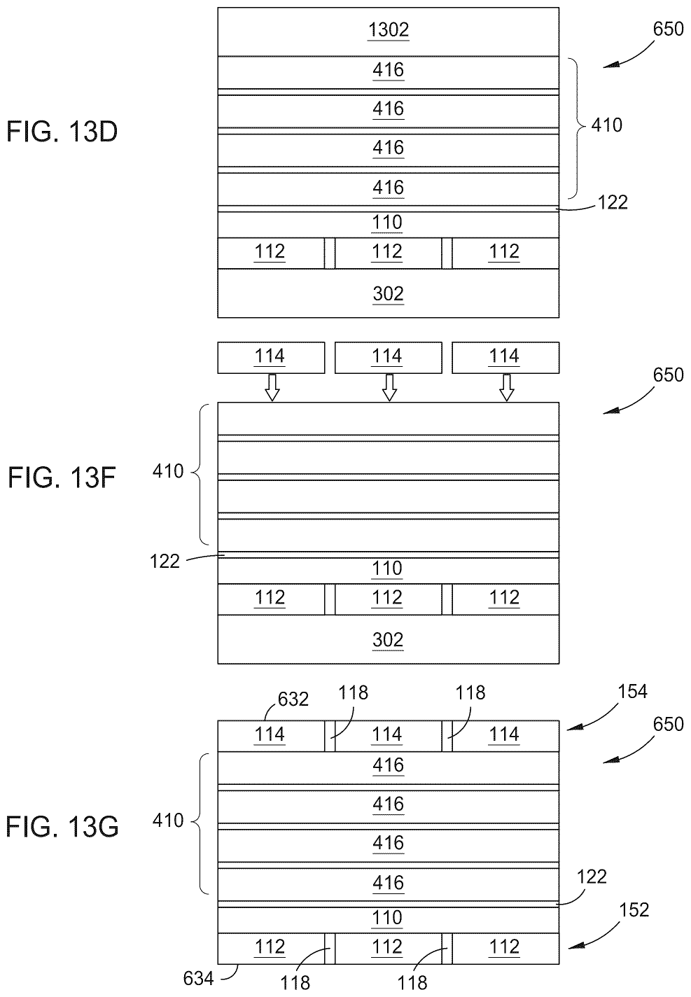

FIG. 12 is a block diagram of a method 1200 for fabricating a chip complex, such as the chip complex 650 or other similar chip complex. The method 1200 may be extended to form a chip package, such as the chip package 400, or other suitable chip package. FIG. 13A through FIG. 13G depict the chip complex 650 in different stages of fabrication.

The method 1200 begins at operation 1202 by mounting a plurality of IC dies 112 on a first carrier substrate 302, as illustrated in FIGS. 13A. The IC dies 112 may be mounted by their backsides to first carrier substrate 302 by diffusion bonding or the other suitable technique. The IC dies 112 diffusion bonded to the carrier substrate 302 generally form a reconstituted wafer.

At operation 1204, the passive interposer 110 is mounted to the IC dies 112 diffusion bonded to the carrier substrate 302, as illustrated in FIG. 13B. The passive interposer 110 may be mounted to the IC dies 112 defining a common tier 152 using wafer-to-wafer mounting or other techniques. In one example, the IC dies 112 are hybrid bonded to the passive interposer 110, for example, by using a hybrid bonding layer 122 (not shown in FIG. 13B). As described above, the passive interposer 110 includes a BEOL region 304 fabricated on a substrate 306. The substrate 306 may be a silicon or other type of wafer on which a routing interconnect may be formed using BEOL techniques. The BEOL techniques used to form the routing interconnect results in routing densities to 120 nm pitch and below.

At operation 1206, the substrate 306 of the passive interposer 110 is thinned to form a thinned interposer 308, as illustrated in FIG. 13C. The substrate 306 may be thinned to less than 50% or even less than 12% of the substrate's pre-thinning original thickness. The substrate 306 may be thinned by grinding, etching, milling or other suitable technique. The substrate 306 may be optionally be completely removed, leaving only the BEOL region 304 as the thinned interposer 308. After the substrate 306 is thinned or removed at operation 1206, a hybrid bonding layer 122 is formed on the exposed side of the passive interposer 110 facing away from the carrier substrate 302.

At operation 1208, a memory stack 410 mounted to a passive interposer 110, as shown in FIG. 13D. The memory stack 410 is hybrid bonded to the passive interposer 110, for example, by using a hybrid bonding layer 122. The memory stack 410 may include a temporary carrier substrate 1302 The memory IC dies 412 of the memory stack 410 are secured together within the memory stack 410 by hybrid bonding, for example, by using a hybrid bonding layer 122 deposed between adjacent memory IC dies 412 and the passive interposer 110.

At operation 1210, a plurality of IC dies 114 are mounted on a side of the memory stack 410 opposite the passive interposer 110, as shown in FIG. 13F. At operation 1212, interstitial space between the IC dies 114 is filed by a dielectric material 118, as illustrated in FIG. 13G. The temporary carrier substrate 302 may also be removed at either of operation 1208 or operation 1210.

The method 1200 continues at operation 1214 by singulatating the individual chip complexes 650 from the reconstituted wafer. Each chip complex 650 can be sold and shipped as a unit to another fabricator who would utilized the chip complex 650 to fabricate a chip package 400. If chip complexes 650 are the desired end product, the method 1200 may end after singulatation. If a chip package 400 is the desired end product, the method 1200 continues at operation 1216 by mounting the chip complex 650 to the optional interposer 102 and/or the package substrate 104 utilizing the solder connections 106/108 or through another suitable technique to form the chip package 400. Optionally at operation 1218, one or more additional chip complexes 470 may be mounted to the interposer 102 and/or the package substrate 104. Also optionally at operation 1218, the chip package 400 may be mounted to the PCB 130 to form the electronic device 460.

Using a hybrid chip-on-wafer hybrid bonding process, the active sides of the common tier IC dies are bonded to metal bond pads exposed on the hybrid bonding layer formed opposite the BEOL side of the substrate. The entire surface of each common tier IC die is bonded to the hybrid bonding layer of the substrate, this significantly increasing the area available for making connections between the routing in the substrate and the bond pads of the second common tier IC dies.

The above disclosed technology may be expressed in the following non-limiting examples. The chip complex, chip package and the electronic device are all examples of integrated circuit (IC) devices.

Example 1. An integrated circuit (IC) chip complex, comprising: a passive interposer, the passive interposer includes an interconnect formed in a back end of the line (BEOL) region; at least a first (IC) die of a first common tier hybrid bonded to a first side of the passive interposer; and at least two or more second (IC) dies of a second common tier hybrid bonded to a second side of the passive interposer.

Example 2. The IC chip complex of example 1, wherein the passive interposer covers an entirety of the first IC die.

Example 3. The IC chip complex of example 2, wherein the passive interposer covers an entirety of a second one of the plurality of first IC dies present in the first common tier.

Example 4. The IC chip complex of example 2, wherein the passive interposer covers an entirety of a first one of the plurality of second IC dies present in the second common tier.

Example 5. The IC chip complex of example 4, wherein the passive interposer covers an entirety of a second one of the plurality of first IC dies present in the second common tier.

Example 6. The IC chip complex of example 1, wherein the passive interposer comprises: a thinned substrate; and vias formed through the thinned substrate, the vias coupled to the interconnect.

Example 7. The IC chip complex of example 6, wherein the passive interposer includes passive routing without the presence of transistors.

Example 8. The IC chip complex of example 1, wherein the BEOL region defines the first and second sides of the passive interposer.

Example 9. The IC chip complex of example 1 further comprising: a silicon block disposed over the first IC die.

Example 10. The IC chip complex of example 1, wherein the first IC die is a memory die.

Example 11. The IC chip complex of example 1, wherein the first IC die is a logic die.

Example 12. The IC chip complex of example 1 further comprising: an active passive interposer die stacked with the passive interposer.

Example 13. An integrated circuit (IC) chip package, comprising: a package substrate; and a chip complex mounted to the package substrate, the chip complex comprising: a passive interposer; at least a first (IC) die of a first common tier hybrid bonded to a first side of the passive interposer; and at least two or more second (IC) dies of a second common tier hybrid bonded to a second side of the passive interposer.

Example 14. The chip package of example 13, wherein the passive interposer covers an entirety of the first IC die present in the first common tier and all the second IC dies present in the second common tier.

Example 15. The chip package of example 14, wherein the substrate includes passive routing without the presence of transistors.

Example 16. The chip package of example 15, wherein the passive interposer comprises: an interconnect disposed in a BEOL region of a thinned substrate; and vias formed through the thinned substrate, the vias coupled to the interconnect.

Example 17. The chip package of example 15, wherein the passive interposer comprises: an interconnect disposed in a BEOL region, the BEOL region comprising the first and second sides of the passive interposer.

Example 18. The chip package of example 13, wherein the first IC die is a memory die or a logic die.

Example 19. A method for forming a chip complex comprising: securing a plurality of IC dies forming a first common tier to a temporary carrier substrate; hybrid bonding the IC dies of the first common tier to a first side of a passive interposer; thinning a second side of the passive interposer; hybrid bonding IC dies of a second common tier to the second side of the passive interposer; and removing the temporary carrier substrate.

Example 20. The method of example 19, wherein hybrid bonding the IC dies of the first common tier to the first side of a passive interposer comprises performing a wafer-to-wafer hybrid bonding process; and wherein hybrid bonding the IC dies of the second common tier to the first side of a passive interposer comprises performing a chip-to-wafer hybrid bonding process.

Example 21. An integrated circuit (IC) memory chip complex, comprising: a passive interposer; a plurality of memory integrated circuit (IC) dies stacked together, one of the memory IC dies hybrid bonded to a first side of the passive interposer; and at least two or more (IC) dies of a first common tier hybrid bonded to a second side of the passive interposer.

Example 22. The IC memory chip complex of example 21, wherein the passive interposer covers an entirety of the memory IC die.

Example 23. The IC memory chip complex of example 22, wherein the passive interposer covers an entirety of a one of the two or more IC dies present in the first common tier.

Example 24. The IC memory chip complex of example 22, wherein the passive interposer covers an entirety of all the IC dies present in the first common tier.

Example 25. The IC memory chip complex of example 24 further comprising: at least two or more (IC) dies of a second common tier hybrid bonded to the IC dies present in the first common tier.

Example 26. The IC memory chip complex of example 25, wherein at least one of the IC dies in the first and second common tiers comprises memory controller circuitry.

Example 27. The IC memory chip complex of example 26, wherein at least one of the IC dies in the first and second common tiers comprises logic circuitry coupled to the at least one IC die comprising memory controller circuitry.

Example 28. The IC memory chip complex of example 21, wherein the passive interposer comprises: an interconnect disposed in a BEOL region of a thinned substrate; and vias formed through the thinned substrate, the vias coupled to the interconnect.

Example 29. The IC memory chip complex of example 28, wherein the substrate includes passive routing without the presence of transistors.

Example 30. The IC memory chip complex of example 21, wherein the passive interposer comprises: an interconnect disposed in a BEOL region, the BEOL region comprising the first and second sides of the passive interposer.

Example 31. An integrated circuit (IC) chip package, comprising: a package substrate; one or more logic IC dies mounted on the package substrate; and a chip complex mounted to the package substrate and communicatively coupled to the one or more logic IC dies through the package substrate, the chip complex comprising: a passive interposer; a plurality of memory IC dies stacked together, one of the memory IC dies hybrid bonded to a first side of the passive interposer; and at least two or more (IC) dies of a first common tier hybrid bonded to a second side of the passive interposer.

Example 32. The chip package of example 31, wherein the passive interposer covers an entirety of the memory IC die.

Example 33. The chip package of example 32, wherein the passive interposer covers an entirety of a one of the two or more IC dies present in the first common tier.

Example 34. The chip package of example 32, wherein the passive interposer covers an entirety of all the IC dies present in the first common tier.

Example 35. The chip package of example 34 further comprising at least two or more (IC) dies of a second common tier hybrid bonded to the IC dies present in the first common tier.

Example 36. The chip package of example 35, wherein at least one of the IC dies in the first and second common tiers comprises memory controller circuitry.

Example 37. The chip package of example 36, wherein at least one of the IC dies in the first and second common tiers comprises logic circuitry coupled to the at least one IC die comprising memory controller circuitry.

Example 38. The chip package of example 31, wherein the passive interposer comprises: an interconnect disposed in a BEOL region of a thinned substrate; and vias formed through the thinned substrate, the vias coupled to the interconnect.

Example 39. The chip package of example 38, wherein the substrate includes passive routing without the presence of transistors.

Example 40. The chip package of example 31, wherein the passive interposer comprises: an interconnect disposed in a BEOL region, the BEOL region comprising the first and second sides of the passive interposer.

While the foregoing is directed to embodiments of the present invention, other and further embodiments of the invention may be devised without departing from the basic scope thereof, and the scope thereof is determined by the claims that follow.

What is claimed is:

1. An integrated circuit (IC) chip complex, comprising:
a passive interposer, the passive interposer includes an interconnect formed in a back end of the line (BEOL) region;
at least a first (IC) die of a first common tier hybrid bonded to a first side of the passive interposer; and
at least two or more second (IC) dies of a second common tier hybrid bonded to a second side of the passive interposer.

2. The IC chip complex of claim 1, wherein the passive interposer covers an entirety of the first IC die.

3. The IC chip complex of claim 2, wherein the passive interposer covers an entirety of a second IC die present in the first common tier.

4. The IC chip complex of claim 2, wherein the passive interposer covers an entirety of a first one of the at least two or more second IC dies present in the second common tier.

5. The IC chip complex of claim 4, wherein the passive interposer covers an entirety of a second one of at least two or more second IC dies present in the second common tier.

6. The IC chip complex of claim 1, wherein the passive interposer comprises:
a thinned substrate; and
vias formed through the thinned substrate, the vias coupled to the interconnect.

7. The IC chip complex of claim 6, wherein the passive interposer includes passive routing without a presence of transistors.

8. The IC chip complex of claim 1, wherein the BEOL region defines the first and second sides of the passive interposer.

9. The IC chip complex of claim 1 further comprising:
a silicon block disposed over the first IC die.

10. The IC chip complex of claim 1, wherein the first IC die is a memory die.

11. The IC chip complex of claim 1, wherein the first IC die is a logic die.

12. The IC chip complex of claim 1 further comprising:
an active passive interposer die stacked with the passive interposer.

13. An integrated circuit (IC) chip package, comprising:
a substrate; and
a chip complex mounted to the substrate, the chip complex comprising:
a passive interposer;
at least a first (IC) die of a first common tier hybrid bonded to a first side of the passive interposer; and
at least two or more second (IC) dies of a second common tier hybrid bonded to a second side of the passive interposer.

14. The chip package of claim 13, wherein the passive interposer covers an entirety of the first IC die present in the first common tier and all the second IC dies present in the second common tier.

15. The chip package of claim 14, wherein the substrate includes passive routing without a presence of transistors.

16. The chip package of claim 15, wherein the passive interposer comprises:
an interconnect disposed in a BEOL region of a thinned substrate; and
vias formed through the thinned substrate, the vias coupled to the interconnect.

17. The chip package of claim 15, wherein the passive interposer comprises:
an interconnect disposed in a BEOL region, the BEOL region comprising the first and second sides of the passive interposer.

18. The chip package of claim 13, wherein the first IC die is a memory die or a logic die.

19. A method for forming a chip complex comprising:
securing a plurality of IC dies forming a first common tier to a temporary carrier substrate;
hybrid bonding the IC dies of the first common tier to a first side of a passive interposer;
thinning a second side of the passive interposer;
hybrid bonding IC dies of a second common tier to the second side of the passive interposer; and
removing the temporary carrier substrate.

20. The method of claim 19,
wherein hybrid bonding the IC dies of the first common tier to the first side of the passive interposer comprises performing a wafer-to-wafer hybrid bonding process; and
wherein hybrid bonding the IC dies of the second common tier to the first side of the passive interposer comprises performing a chip-to-wafer hybrid bonding process.
